(19) United States
(12) Patent Application Publication
(10) Pub. No.: US 2025/0218774 A1
(43) Pub. Date: Jul. 3, 2025

(54) HIGH ENERGY ATOMIC LAYER ETCH OF A CARBON CONTAINING LAYER

(71) Applicant: Lam Research Corporation, Fremont, CA (US)

(72) Inventors: Wenbing YANG, Campbell, CA (US); Baichang LI, San Jose, CA (US); Arunima Deya BALAN, Mountain View, CA (US); Yiwen FAN, Fremont, CA (US); Samantha SiamHwa TAN, Newark, CA (US); Patrick August VAN CLEEMPUT, Castle Rock, WA (US); Yang PAN, Los Altos, CA (US); Younghee LEE, Pleasanton, CA (US); Alexander Declan BENNET, San Jose, CA (US); Roger PATRICK, Mountain View, CA (US); Derek WITKOWICKI, San Jose, CA (US); Young Ah LEE, Fremont, CA (US); Clint Edward THOMAS, Timnath, CO (US)

(21) Appl. No.: 18/847,632

(22) PCT Filed: Mar. 17, 2023
(86) PCT No.: PCT/US2023/015526

§ 371 Date: Sep. 16, 2024

Related U.S. Application Data
(60) Provisional application No. 63/345,655, filed on May 25, 2022.
(60) Provisional application No. 63/322,535, filed on Mar. 22, 2022.

(51) Int. Cl. H01L 21/033; H01L 21/308; H01L 21/311; H01L 21/3213

(52) U.S. Cl. CPC H01L 21/0337; H01L 21/0332; H01L 21/0338; H01L 21/3081; H01L 21/3086; H01L 21/3088; H01L 21/31144; H01L 21/32139

(57) ABSTRACT

A method comprises a plurality of cycles, wherein each cycle, comprises exposing the carbon containing etch layer to oxygen radicals to modify part of the carbon containing etch layer. The carbon containing etch layer is exposed to bombardment ions with an energy greater than 100 eV for less than 0.5 seconds, wherein the bombardment ions remove the modified part of the carbon containing etch layer to form etched features.

### CROSS-REFERENCE TO RELATED APPLICATION

This application claims the benefit of priority of U.S. Application No. 63/322,535, filed Mar. 22, 2022, and U.S. Application No. 63/345,655, filed May 25, 2022, which are incorporated herein by reference for all purposes.

### BACKGROUND

The background description provided here is for the purpose of generally presenting the context of the present disclosure. Anything described in this background section, and potentially aspects of the written description, are not expressly or impliedly admitted as prior art with respect to the present application.

The disclosure relates to a method of forming semiconductor devices on a semiconductor wafer. More specifically, the disclosure relates to the selective etching of semiconductor devices.

In the formation of semiconductor devices, various layers may be selectively etched. Atomic layer etching may be used to provide an etch with high selectivity. Because atomic layer etching may remove a few atomic layers for each cycle, atomic layer etch speed is dependent on the period of each cycle.

Atomic layer etching processes are described in U.S. Pat. No. 10,566,212, entitled “Designer Atomic Layer Etching,” by Kanarik, issued Feb. 18, 2020, U.S. Pat. No. 10,763,083, entitled “High Energy Atomic Layer Etching,” by Yang et al., issued Sep. 1, 2020, US 2021/0005425A1, entitled “Atomic Layer Etching and Smoothing of Refractory Metals and Other High Surface Binding Energy Materials,” by Yang et al., published Jan. 2, 2021, and WO 2020/223152A1, entitled “Atomic Layer Etching for Subtractive Metal Etch,” by Yang et al., published on Nov. 5, 2020, which are all incorporated by references for all purposes.

In addition, U.S. Pat. No. 10,685,836, entitled “Etching Substrates Using ALE and Selective Deposition” by Tan et al. issued Jun. 16, 2020, which is incorporated by reference for all purposes, discloses a process for providing an atomic layer etch (ALE) of a carbon containing layer using a low voltage bias. U.S. Pat. No. 10,304,659 entitled “ALE Smoothness: In and Outside Semiconductor Industry” by Kanarik et al. issued May 28, 2019, which is incorporated by reference for all purposes, discloses a process for providing an atomic layer etch (ALE) of a carbon containing layer, such as amorphous carbon, using a low voltage bias. The low bias is used to reduce or prevent physical sputtering.

For etching a carbon containing layer below a hardmask, an oxygen containing reactive-ion etch may be used. A reactive ion etch may use high energy ions at a low pressure in order to etch the etch layer. The reactive ion etch may not provide a desired etch selectivity.

### SUMMARY

To achieve the foregoing and in accordance with the purpose of the present disclosure, a method for etching a carbon containing etch layer is provided. The method comprises a plurality of cycles, wherein each cycle, comprises exposing the carbon containing etch layer to oxygen radicals to modify part of the carbon containing etch layer. The carbon containing etch layer is exposed to bombardment ions with an energy greater than 100 eV for less than 0.5 seconds, wherein the bombardment ions remove the modified part of the carbon containing etch layer to form etched features.

In another manifestation, an etching system for etching a carbon containing etch layer over a substrate, the etching system is provided. A substrate support supports a substrate in a processing chamber. An RF power source provides RF power to etch chamber. An oxygen radical source is adapted to provide oxygen radicals in the processing chamber. A bombardment gas source is adapted to provide bombardment gas in the processing chamber. A controller is controllably connected to the RF power source, the oxygen radical source, and the bombardment gas source. The controller is configured to provide a plurality of cycles where each cycle exposes the carbon containing etch layer to oxygen radicals where the oxygen radicals are absorbed into the carbon containing etch layer to form a modified part of the carbon containing etch layer and exposes the etch layer to bombardment ions with an energy greater than 100 eV for a time less than 0.5 seconds wherein the bombardment ions remove the modified part of the carbon containing etch layer.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart according to some embodiments.

FIGS. 2A-C are schematic cross-sectional views of an example stack processed according to some embodiments.

FIGS. 3A-C are detailed schematic views of an example etch layer processed according to some embodiments.

FIG. 4A is a graph that illustrates the number of angstroms (Å) etched per cycle during an ALE etched according to some embodiments and for a modification step alone and a removal step alone at different pulse bias voltages.

FIG. 4B is a graph of the synergy from the data in FIG. 4A.

FIG. 5A is a graph that illustrates the number of angstroms (Å) etched per cycle during an ALE etched according to other embodiments and for a modification step alone and a removal step alone at different pulse bias voltages.

FIG. 5B is a graph of the synergy from the data in FIG. 5A.

FIG. 6A is a cross-sectional side view of an example of a carbon containing etch layer that has been etched according to some embodiments.

FIG. 6B is a perspective view of the carbon containing etch layer, shown in FIG. 6A.

FIG. 7A is a cross-sectional side view of an example of a carbon containing etch layer that has been etched according to other embodiments without passivation.

FIG. 7B is a perspective view of the carbon containing etch layer, shown in FIG. 7A.

FIG. 8A is a cross-sectional side view of an example of a carbon containing etch layer that has been etched according to other embodiments with passivation.

FIG. 8B is a perspective view of the carbon containing etch layer, shown in FIG. 8A.

FIG. 9 is a schematic view of an example plasma processing chamber that may be used in some embodiments.

FIG. 10 is a schematic view of an example computer system that may be used in practicing some embodiments.

FIG. 11A-D are schematic views of a stack that is processed according to some embodiments.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

In the formation of semiconductor devices, various layers may be selectively etched. Atomic layer etching may be used to provide an etch with high selectivity. In an atomic layer etch (ALE), a cyclical process is provided. The cyclical process may have a first step of modifying part of an etch layer and a second step of removing the modified part of the etch layer. Such an ALE may use a self-limiting process to modify part of the etch layer. The self-limiting process may modify a few monolayers of the etch layer forming a self-limiting layer. In such a case, the removing of the modified part of the etch layer may remove just a few atomic layers of the etch layer. As a result, many cycles are needed in order to etch a substantial part of the etch layer. Each cycle may be more than 12 seconds long. As a result, an ALE process may take a long time in order to etch a substantial part of an etch layer.

ALE processes used to etch carbon containing etch layers, such as amorphous carbon, use low bias voltages. In such processes, the low bias voltages may be applied for several seconds in order to provide an ALE while preventing or reducing sputtering caused by higher biases. Some of the drawbacks to such processes using a low bias are that such ALE processes are slower and the ions under a low bias for the ALE process are not highly directional. Since the ions are not highly directional, the resulting features do not have a high height to width aspect ratio.

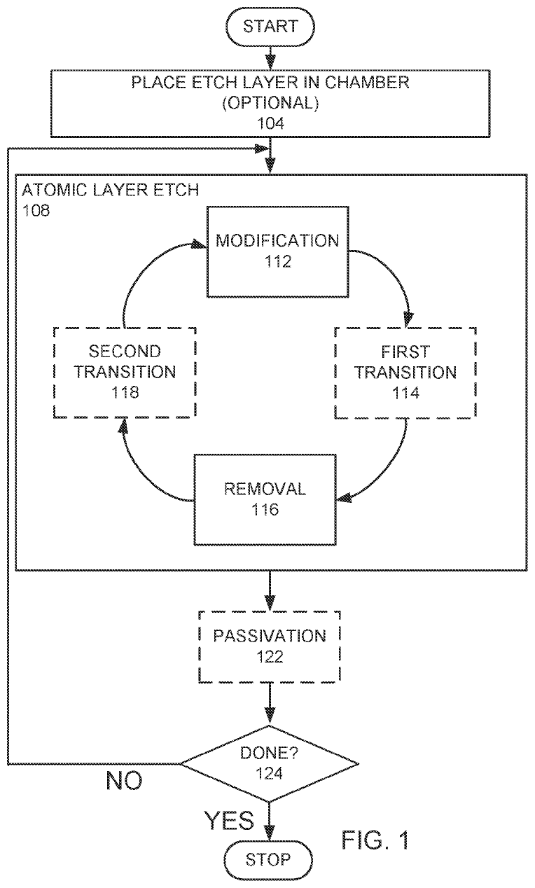

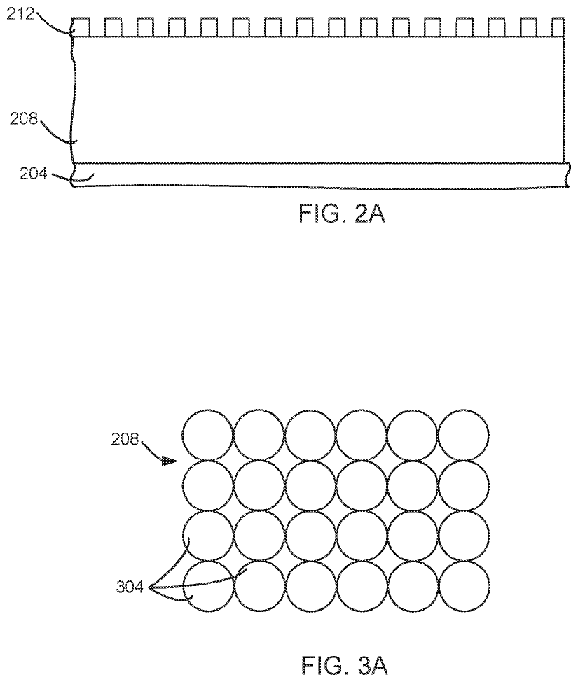

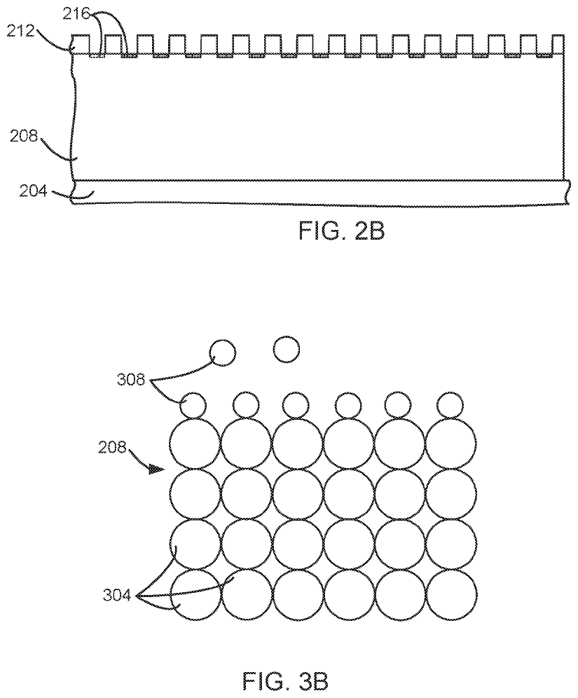

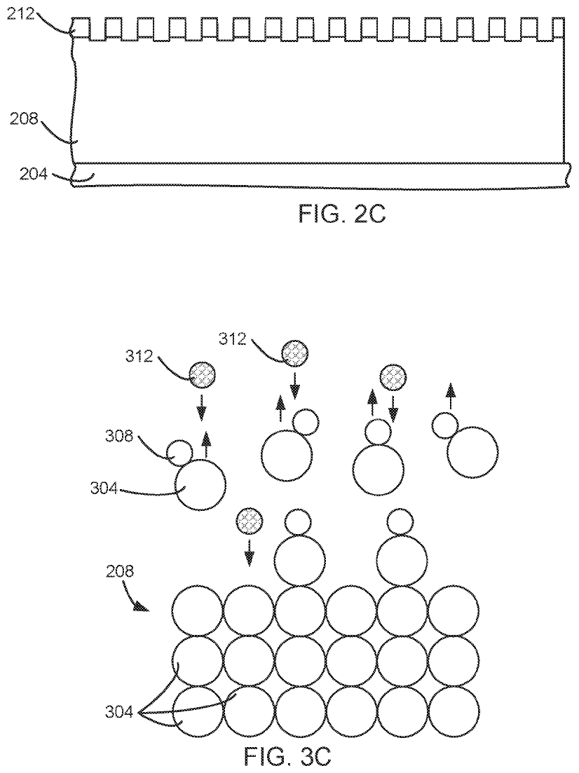

To facilitate understanding, FIG. 1 is a high level flow chart illustrating processes used in some embodiments. As shown, carbon containing etch layer over a substrate and under a mask is placed in a processing chamber (step 104). FIG. 2A is a schematic cross-sectional view of an example wafer 204 under a carbon containing etch layer 208 disposed below a mask 212. In some embodiments, the carbon containing etch layer 208 is a carbon based layer. In various embodiments, the mask may be formed from photoresist, for example, extreme ultraviolet (EUV) photoresist, metal-containing photoresist, organometallic photoresist, tin-containing photoresist, tin-oxide containing photoresist, and organotin photoresist. In other embodiments, the mask may not be made of a photoresist material. FIG. 3A is a schematic view of an enlarged section of an exposed portion of the carbon containing etch layer 208 showing carbon atoms 304, therein.

The carbon containing etch layer 208 is etched using an atomic layer etch (step 108). The atomic layer etch (step 108) is a cyclical process where in each cycle an exposed surface of the carbon containing etch layer 208 is modified (step 112). In some embodiments, a modification gas is provided. In various embodiments, the modification gas comprises an oxygen containing component. The oxygen containing component may be at least one or more of oxygen gas (O₂), carbon dioxide (CO₂), carbon monoxide (CO), carbonyl sulfide (COS), sulfur dioxide (SO₂), and water (H₂O). In some embodiments, the oxygen containing component of (O₂) may provide an improved ALE process. In some embodiments, CO₂ is used to provide the oxygen containing component and to provide carbon for sidewall passivation to reduce sidewall undercutting. The modification gas is transformed into a plasma comprising oxygen radicals. In some embodiments, the plasma is formed by providing about 100 Watts of RF power at 13.56 megahertz (MHz). In various embodiments, more than 100 Watts or more than 2000 Watts of RF power is provided. In some embodiments, the pressure is between 10 mTorr and 500 mTorr. For example, a pressure of about 40 mTorr is provided. A higher pressure increases the number of ions that are transformed into neutral radicals. In some embodiments, the oxygen radicals may be oxygen ions or neutral oxygen radicals. An electric charge may be used to repel ions from the carbon containing etch layer 208. If a bias is provided, in some embodiments, the bias is less than 50 eV. Low or no bias is provided during the surface modification since the modification process is not removing any material. For example, some embodiments do not provide a bias during the modification step (step 112). Since, low or no bias is provided, neutral oxygen radicals provide the modification, instead of oxygen ions. The oxygen radicals form a bond with carbon from the carbon etch layer, resulting in a modification of a carbon etch layer region.

FIG. 2B is a schematic cross-sectional view of an example wafer 204 under the carbon containing etch layer 208 disposed below the mask 212 after an exposed portion of the carbon containing etch layer 208 has been modified. The modified portion is schematically illustrated by the shaded regions 216. The shaded regions 216 are not drawn to scale in order to facilitate understanding since, in this example, only a few atomic layers are modified. In various embodiments, from about 1 to 30 atomic or molecular layers are modified. FIG. 3B is a schematic view of an enlarged section of an exposed portion of the carbon containing etch layer 208 after part of the exposed portion of the etch layer 208 has been modified. Some of the radical oxygen atoms 308 form bonds with exposed carbon atoms 304. In some embodiments, some of the carbon containing etch layer 208 may be etched away during the modification step.

After the modification (step 112), a first transition is provided (step 114). The first transition removes the modification gas and provides a bombardment gas (also called a removal gas). In various embodiments, the bombardment gas is one or more of hydrogen (H₂), nitrogen (N₂), helium (He), neon (Ne), argon (Ar), krypton (Kr), and xenon (Xe). For example, the bombardment gas comprises Ar, which is readily available and has a higher mass than He and Ne. In various embodiments, the first transition is accomplished in the range of 1 ms to 500 ms. In some embodiments, the first transition is completed in the range of 0.1 s to 3 s. For example, the first transition is accomplished in less than 0.5 s.

After the first transition (step 114), a removal step is provided (step 116). In some embodiments, the pressure is 1 mTorr to 25 mTorr. In some embodiments, the pressure of the modification gas is at least 10 mTorr more than the pressure of the bombardment gas. For example, the bombardment gas is provided at a pressure of about 5 mTorr. The lower pressure of the bombardment gas results in fewer collisions in the bombardment plasma allowing for a more directional ion flow. It is more important for the bombardment ions to be directional than the modification ions so that the bombardment ions are able to provide higher aspect ratio features. In some embodiments, more than 500 Watts of RF power is provided. For example, the bombardment gas is transformed into a plasma by providing 300 Watts of RF power at 13.56 MHz. In some embodiments, the bias is in the range of 100 eV to 2000 eV. In various embodiments, the bias is in the range of 400 eV to 1500 eV. In other embodiments, the bias is greater than 500 eV. The higher energy bias provides more directional ions. In some embodiments, the ions are highly vertically directional in order to form high depth to width vertical features. Previously, such high biases were avoided in order to prevent physical sputtering, because physical sputtering is not selective. Some embodiments avoid or reduce physical sputtering by providing a bias for a short period of time. The bias is applied for a long enough period of time to provide the removal of the modified parts of the etch layer and a short enough time to reduce or eliminate physical sputtering. In some embodiments, the bias is provided for a period of 0.3 ms to 500 ms. In some embodiments, the bias is provided for a period in the range of 5 ms to 300 ms.

In some embodiments, the bias is applied as a continuous bias for a period of 0.3 ms to 500 ms for a removal step (step 116) of a cycle. Therefore, in some embodiments, the removal step is provided for a period of 0.3 ms to 500 ms. In some embodiments, a pulsed bias is provided. For example, the bias may be pulsed at 100 Hz with a 10% duty cycle. In such an example, the bias would be applied for 1 ms for each bias pulse at 100 Hz. In this example, if the removal step is provided for 2 seconds, then the bias would be applied for 10% of the 2 seconds, which would be 0.2 seconds or 200 ms. With a pulsed bias, some embodiments provide a bias for a total period of 0.3 ms to 500 ms during a removal step (116) of a cycle in order to reduce physical sputtering. At a 10% duty cycle, the removal step (step 116) for each cycle would be from 3 ms to 5000 ms long. Different embodiments may provide different duty cycles from 1% to 100% and different frequencies. In some embodiments, the removal step is provided for a time between 10 ms and 6000 ms. In some embodiments, the removal step is provided for a time between 100 ms and 6000 ms.

Having a higher ion flux allows for a faster removal step (step 116) without increasing physical sputtering. However, the flux should be low enough to minimize collisions between bombardment ions, so that the ions are directional. In some embodiments, the flux of the ions is between about 10¹⁵ to 10²⁰ ions/cm²s. In some embodiments, the flux of ions near the modified layer is greater than 10¹⁷ ions/cm²s. The higher flux and higher energy ion bombardment reduces the time needed for the removal step.

FIG. 2C is a schematic cross-sectional view of a wafer 204 under the carbon containing etch layer 208 disposed below the mask 212 after the removal step (step 116). The modified portion has been removed. FIG. 3C is a schematic view of an enlarged section of an exposed portion of the carbon containing etch layer 208 during the removal step. Argon ions (Ar⁺) 312, bombard the carbon containing etch layer causing modified carbon atoms 304 bound with oxygen atoms 308 to be removed.

After the removal step (step 116), a second transition is provided (step 118). The second transition removes the bombardment gas and provides the modification gas. In some embodiments, the second transition is accomplished less than 0.5 s. In various embodiments, the second transition is accomplished in the range of 1 ms to 0.5 s. In some embodiments, the first transition is completed in the range of 0.1 s to 3 s.

The cycle of the steps of modification (step 112), first transition (step 114),

removal (step 116), and second transition (step 118) is repeated a plurality of times until features are etched to a desired depth.

In some embodiments, an optional passivation (step 122) is provided. During the passivation step, a passivation gas is provided. In some embodiments, the passivation gas is tungsten hexafluoride (WF₆). In some embodiments, the passivation gas is transformed into a plasma. Passivation is formed on sidewalls of etched features to passivate sidewalls in order to reduce undercutting during subsequent etch steps. In some embodiments, the passivation (step 122) is provided in a separate step at a different time from the atomic layer etch (step 108). In other embodiments, the passivation (step 122) is provided simultaneously with the atomic layer etch (step 108). In some embodiments, where the passivation (step 122) is provided simultaneously with the atomic layer etch (step 108) the passivation gas is provided simultaneously with at least one of exposing the carbon containing etch layer to oxygen radicals and exposing the carbon containing layer to bombardment ions. In some embodiments, the carbon containing layer is a carbon hardmask, such as being an amorphous carbon layer. In other embodiments, the carbon containing layer is not a carbon hardmask, which is a weaker carbon with dangling bonds. For example, the carbon containing layer may be an underlayer under a mask. Such, carbon containing material that is not a hardmask with weak dangling bonds is more subject to sidewall etching and undercutting. As a result, passivation is more helpful to protect sidewalls when the carbon containing layer is not a hardmask carbon material. In some embodiments, using CO₂ as the modification gas provides carbon for sidewall passivation. When CO₂ is used as the modification gas, the resulting plasma provides oxygen radicals for modifying the carbon etch layer and carbon species that provide passivation of sidewalls of etch features. In some embodiments, other carbon-containing gases, such as methane (CH₄), fluoromethane (CH₃F), and CO may be added to provide carbon for sidewall passivation. The ratio of carbon containing gases to oxygen containing gases may be used as a knob to adjust sidewall passivation. In some embodiments, the passivation may be provided by providing nitrogen (N₂) gas with methane. The nitrogen combines with the carbon from methane to form a carbon and nitrogen based passivation layer. In some embodiments, boron trichloride (BCl₃) and N₂ may be used to provide a boron nitride passivation. In some embodiments, a silicon based passivation may be provided.

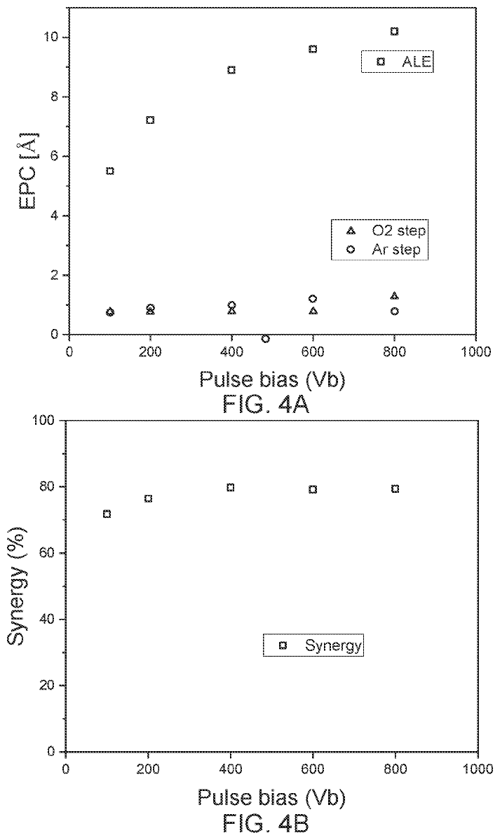

FIG. 4A is an example graph that illustrates the number of angstroms (Å) of the carbon containing etch layer is etched per cycle during an ALE etched according to some embodiments and for a modification step alone and a removal step alone at different pulse bias voltages. FIG. 4A shows that at bias voltages ranging from 100 Volts to 800 Volts using the parameters in the above embodiment, the modification step alone etches about 0.8 Å for each cycle and the removal step without a modification step etches in the range of about 0.7 Å to 1.3 Å for each cycle. FIG. 4A further shows that an ALE that cyclically provides the modification step (step 112) followed by the removal step (step 116) at a bias of about 800 Volts etches about 10 Å per cycle, while the removal step without a modification step at a bias of about 800 Volts etches about 1.3 Å. Therefore, at a bias of about 800 Volts, the modification step alone etches about 0.8 Å, while the removal step alone etches about 1.3 Å, for a total of about 2.1 Å. However, an ALE cycle of the modification step followed by the removal step at a bias of about 800 Volts removes about 10 Å. As a result, the ALE etches about 5 times the amount etched by the individual modification step and removal steps by themselves. This means that the modification step and removal step combined in a cyclical ALE process have a synergy of about 80%, where synergy is defined by the equation:

$$S = \vert ( ALE - ( M + R ) ) / ALE ] \times 100 \% \qquad ( 1 )$$

Where S is synergy (%), M is the number of Å etched each cycle by the modification step alone without the removal step, R is the number of Å etched each cycle by the removal step alone without the modification step, and ALE is the number of Å etched each for each ALE cycle of the ALE process.

FIG. 4B is a graph of the synergy from the data in FIG. 4A. At bias voltages in the range of 400 Volts to 800 Volts the synergy is about 80%.

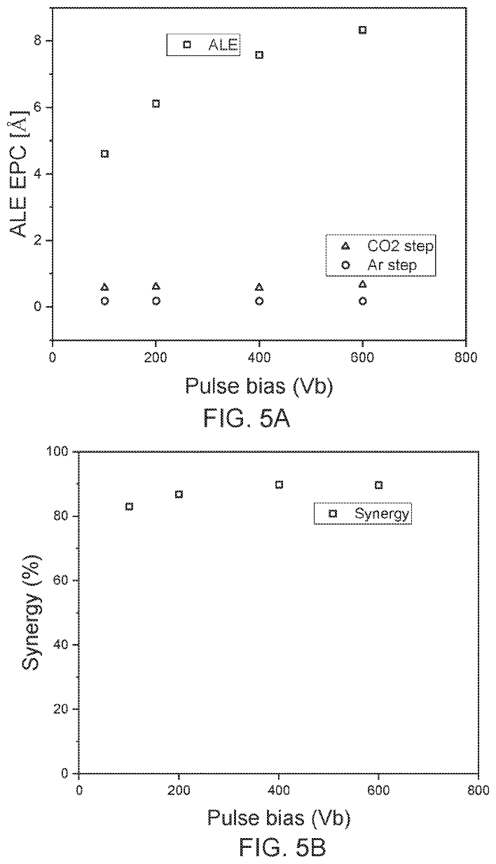

In some embodiments, the modification gas is CO₂ provided at a pressure of about 40 mTorr. 100 W of TCP power is provided for about 1 second for each cycle. The parameters of the removal step are the same as in the previous embodiment. FIG. 5A is a graph that illustrates the number of Å etched per cycle during an ALE etched in some embodiments and for a modification step alone and a removal step alone at different pulse bias voltages. FIG. 5B is a graph of the synergy from the data in FIG. 5A. At bias voltages in the range of 200 Volts to 800 Volts, a synergy greater than 80% is obtained.

Using an atomic layer etch process allows for a highly selective etch of the carbon containing etch layer 208 with respect to the mask 212. Etching by physical sputtering has a lower selectivity than the atomic layer etching process that first modifies the carbon etch layer and selectively removes the modified parts of the carbon etch layer.

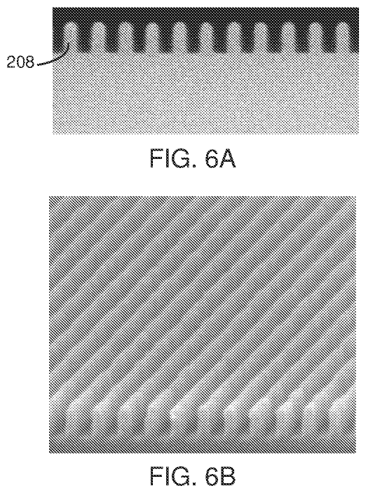

FIG. 6A is a cross-sectional side view of a carbon containing etch layer 208 that has been etched according to an embodiment where the modification gas comprises CO₂ and where no passivation gas is provided. In this embodiment, the carbon containing etch layer 208 is a carbon hardmask. FIG. 6B is a perspective view of the carbon containing etch layer 208, shown in FIG. 6A.

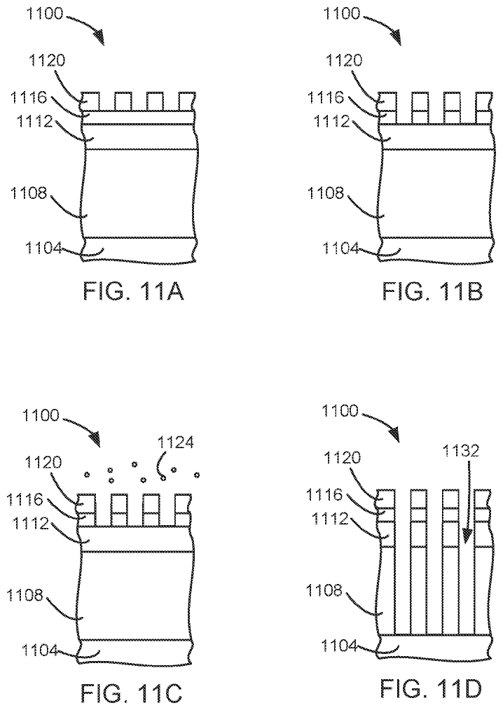

FIG. 11A is a schematic view of a stack 1100 that may be etched in some embodiments. In some embodiments, the stack 1100 comprises a wafer 1104 under an etch layer 1108 disposed below a carbon hardmask layer 1112, disposed below an underlayer 1116 disposed below an extreme ultra-violet (EUV) mask 1120. In some embodiments, one or more layers may be between various layers. In some embodiments, the underlayer 1116 is a material that provides an enhanced performance of the EUV mask 1120 by allowing a reduced EUV dose for the patterning of the EUV mask 1120. In some embodiments, the carbon hardmask layer 1112 is amorphous carbon. Examples of carbon hardmask layer 1112, the EUV mask 1120, and the underlayer 1116 that may be used in some embodiments are described in WO 2021/146138A1, by Xue et al., entitled, “Underlayer for Photoresist Adhesion and Dose Reduction,” published on Jul. 22, 2021, which is incorporated by reference for all purposes

In some embodiments, the underlayer 1116 is etched, transferring the pattern of the EUV mask 1120 to the underlayer 1116. FIG. 11B is a schematic view of the stack 1100 after the underlayer 1116 is etched. The pattern of the EUV mask 1120 has been transferred to the underlayer 1116.

After the pattern has been transferred to the underlayer 1116, in some embodiments, the sidewalls of the underlayer 1116 are passivated. In some embodiments, a plasma formed from WF₆ is used to provide sidewall passivation of the underlayer 1116. FIG. 11C schematically illustrates how sidewalls of the underlayer 1116 are exposed to plasma components 1124 from a plasma formed from WF₆.

During or after passivation of the sidewalls of the underlayer 1116, the carbon hardmask layer 208 is etched using an atomic layer etch (step 108), as shown in FIG. 1. In some embodiments the etching of the carbon hardmask layer 208 is provided after passivation of sidewalls of the underlayer 1116. In some embodiments, the etching of the carbon hardmask layer 208 occurs during the passivation of sidewalls of the underlayer 1116. In some embodiments, passivation of the sidewalls of the underlayer 1116 occurs both before and during the etching of the carbon hardmask layer 208.

In some embodiments, the atomic layer etch (step 108) is a cyclical process where in each cycle an exposed surface of the carbon containing etch layer 208 is modified (step 112). In some embodiments, a modification gas is provided. In various embodiments, the modification gas comprises an oxygen containing component. In some embodiments, the modification gas further comprises a passivation component. In some embodiments, the passivation component is WF₆. In some embodiments, the modification gas is transformed into a plasma comprising oxygen radicals. In some embodiments, the oxygen radicals or ions form a bond with carbon from the carbon etch layer, resulting in a modification of a carbon etch layer region. In some embodiments, the passivation component WF₆ provides passivation on the sidewalls of the underlayer 1116 during the modification step (step 112).

In some embodiments, after the modification step (step 112), a removal step is provided (step 116). In some embodiments, a bombardment gas is provided, and RF power is used to form the bombardment gas into a plasma. In some embodiments, a passivation gas is provided during the modification step (step 112). In some embodiments, the passivation gas comprises WF₆. In some embodiments, components from the passivation gas provide passivation on the sidewalls of the underlayer 1116, during the removal step (step 116). In some embodiments, a bias in the range of 100 eV to 2000 eV is provided. A higher energy bias provides more directional ions. In some embodiments, the ions are highly vertically directional in order to form high depth to width vertical features. The bias is applied for a long enough period of time to provide the removal of the modified parts of the etch layer and a short enough time to reduce or eliminate physical sputtering. In some embodiments, the bias is provided for a period of 0.3 ms to 500 ms.

FIG. 11B is a schematic view of the stack 1100 after the atomic layer etch (step 108) has completed the etching of the etch layer 1108. The atomic layer etch (step 108) etches features 1132 into the etch layer 1108.

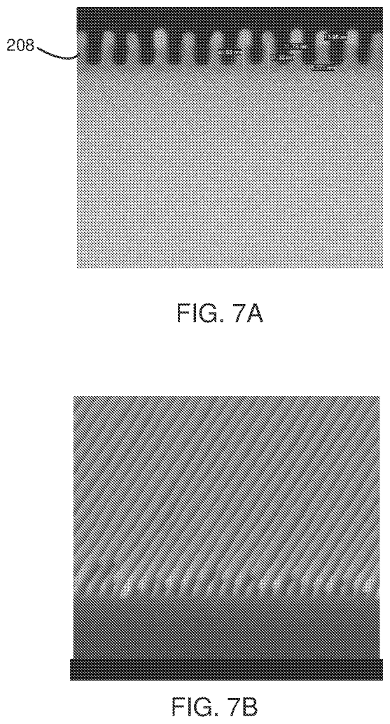

In order to show how the use of a passivation gas comprising WF₆ improves the results, FIG. 7A is a cross-sectional side view of a carbon containing etch layer 208 that has been etched according to an embodiment where the modification gas comprises O₂ and where no passivation gas is provided. FIG. 7B is a perspective view of the carbon containing etch layer 208, shown in FIG. 7A. The ALE process causes undercutting of the carbon containing etch layer 208, as shown in FIG. 7A and FIG. 7B.

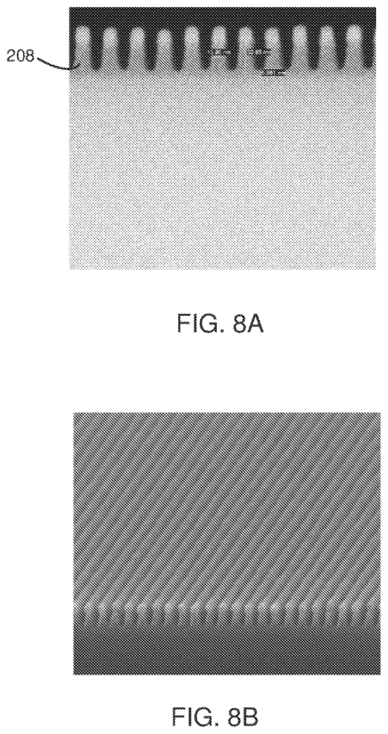

FIG. 8A is a cross-sectional side view of a carbon containing etch layer 208 that has been etched according to an embodiment where the modification gas comprises O₂ and where a passivation gas comprising WF₆ is provided in a passivation step (step 122). FIG. 8B is a perspective view of the carbon containing etch layer 208, shown in FIG. 8A. The passivation step (step 122) reduces the undercutting of the carbon containing etch layer 208 caused by the ALE, as shown in FIG. 8A and FIG. 8B. As a result, the etched features and resulting ridges are more uniform and vertically straight.

The ion dose required to remove the modified surface is defined by ion flux, ion energy, and exposure time. The fractional surface reacted is given by θ as follows:

$$θ ( t ) ≡ \frac{{[ S ]}_{t}}{[ {N}_{0} ]} = ( 1 - {e}^{- Y F t} ) \qquad ( 2 )$$

where θ(t) represents the removal amount as a function of time, where Y(ε) is the ion yield for removing a product (0.1 ions at 0 eV, whereby Y(ε)˜\sqrt{εᵢ}−\sqrt{εₜₕ} is determined by the ion energy), F is the ion flux, and t is the removal time. The traditional ALE operates at a lower ion energy regime for a period of a few seconds, typically around the threshold voltage to sputter the substrate. The high energy ALE in various embodiments applies a very short time with higher ion energy, reducing the exposure time from seconds to milliseconds, thus reducing the time period by 10 to 100 times. As a result, various embodiments provide a high energy ALE process window with a wide range of ion energies. The very short exposure to high energy ions suppresses the sputter of photoresist or other materials that could be used as a hardmask during the etch of the carbon containing etch layer. Therefore, the high energy ALE regime could achieve high selectivity for etching a carbon containing etch layer.

In various embodiments, the bombardment gas may comprise Ar, helium (He), neon (Ne), krypton (Kr), and xenon (Xe). In some embodiments, the bombardment gas consists essentially of Ar, He, Ne, Kr, and Xe. The bombardment ions must have enough energy to sputter the oxygen modified carbon surface while providing minimum or no sputtering of the unmodified carbon surface.

In various embodiments, the carbon containing layer may be an amorphous carbon layer that has some hydrogen. The carbon containing layer may be used as a mask for etching a stack comprising at least one of a silicon containing layer, such as silicon oxide, silicon carbide, silicon nitride or polysilicon, an oxide layer, or a nitride layer, such as titanium nitride. In some embodiments, the stack may comprise alternating layers. The alternating layers may be alternating layers of silicon oxide and polysilicon forming an OPOP stack or may be alternating layers of silicon oxide and silicon nitride forming an ONON stack or may be alternating layers of silicon oxide and tin nitride.

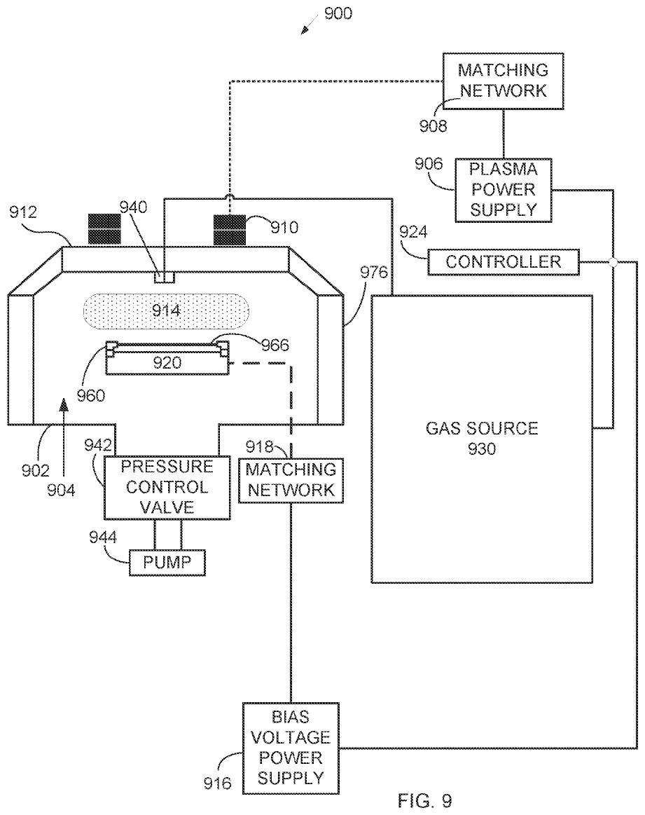

To provide an embodiment of a processing chamber that may be used in an embodiment, FIG. 9 schematically illustrates an example of a processing chamber system 900, such as an etching system, that may be used for the plasma processing process. The processing chamber system 900 includes a plasma reactor 902 having a plasma processing confinement chamber 904, such as an etch chamber, therein. A plasma power supply 906, such as an RF power source, tuned by a plasma matching network 908, supplies power to a transformer coupled plasma (TCP) coil 910 located near a dielectric inductive power window 912 to create a plasma 914 in the plasma processing confinement chamber 904 by providing an inductively coupled power.

The TCP coil (upper power source) 910 may be configured to produce a uniform diffusion profile within the plasma processing confinement chamber 904. For example, the TCP coil 910 may be configured to generate a toroidal power distribution in the plasma 914. The dielectric inductive power window 912 is provided to separate the TCP coil 910 from the plasma processing confinement chamber 904 while allowing energy to pass from the TCP coil 910 to the plasma processing confinement chamber 904. The TCP coil 910 acts as an electrode for providing radio frequency (RF) power to the plasma processing confinement chamber 904. A wafer bias voltage power supply 916 tuned by a bias matching network 918 provides power to an electrode 920 to set the bias voltage on the substrate 966. The substrate 966 is supported by the electrode 920 so that the electrode acts as a substrate support. A controller 924 controls the plasma power supply 906 and the wafer bias voltage power supply 916.

The plasma power supply 906 and the wafer bias voltage power supply 916 may be configured to operate at specific radio frequencies such as, for example, 13.56 megahertz (MHz), 27 MHz, 2 MHz, 60 MHz, 400 kilohertz (kHz), 2.54 gigahertz (GHz), or combinations thereof. Plasma power supply 906 and wafer bias voltage power supply 916 may be appropriately sized to supply a range of powers in order to achieve the desired process performance. For example, in one embodiment, the plasma power supply 906 may supply power in a range of 50 to 5000 Watts, and the wafer bias voltage power supply 916 may supply a bias voltage in a range of 20 to 2000 V. In addition, the TCP coil 910 and/or the electrode 920 may be comprised of two or more sub-coils or sub-electrodes. The sub-coils or sub-electrodes may be powered by a single power supply or powered by multiple power supplies.

As shown in FIG. 9, the processing chamber system 900 further includes a gas source/gas supply mechanism 930, such as a bombardment gas source, oxygen radical source, and passivation gas source. The gas source 930 is in fluid connection with plasma processing confinement chamber 904 through a gas inlet, such as a gas injector 940. The gas injector 940 may be located in any advantageous location in the plasma processing confinement chamber 904 and may take any form for injecting gas. Preferably, however, the gas inlet may be configured to produce a “tunable” gas injection profile. The tunable gas injection profile allows independent adjustment of the respective flow of the gases to multiple zones in the plasma process confinement chamber 904. More preferably, the gas injector is mounted to the dielectric inductive power window 912. The gas injector may be mounted on, mounted in, or form part of the power window. The process gases and by-products are removed from the plasma process confinement chamber 904 via a pressure control valve 942 and a pump 944. The pressure control valve 942 and pump 944 also serve to maintain a particular pressure within the plasma processing confinement chamber 904. The pressure control valve 942 can maintain a pressure of less than 1 torr during processing. An edge ring 960 is placed around the substrate 966. The gas source/gas supply mechanism 930 is controlled by the controller 924. An example of such a plasma processing chamber system 500 is described in PCT application PCT/US21/31490, entitled Distributed Plasma Source Array, filed on May 10, 2021, which is incorporated by reference for all purposes.

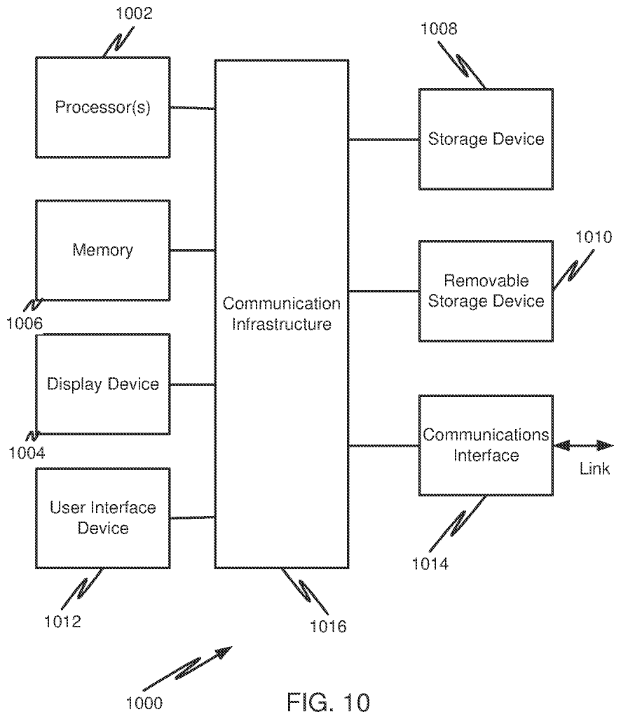

FIG. 10 is a high level block diagram showing a computer system 1000. The computer system 1000 is suitable for implementing a controller 924 used in embodiments. The computer system 1000 may have many physical forms ranging from an integrated circuit, a printed circuit board, and a small handheld device up to a huge supercomputer. The computer system 1000 includes one or more processors 1002, and further can include an electronic display device 1004 (for displaying graphics, text, and other data), a main memory 1006 (e.g., random access memory (RAM)), a storage device 1008 (e.g., hard disk drive), a removable storage device 1010 (e.g., optical disk drive), user interface devices 1012 (e.g., keyboards, touch screens, keypads, mice or other pointing devices, etc.), and a communications interface 1014 (e.g., wireless network interface). The communications interface 1014 allows software and data to be transferred between the computer system 1000 and external devices via a link. The system may also include a communications infrastructure 1016 (e.g., a communications bus, cross-over bar, or network) to which the aforementioned devices/modules are connected.

Information transferred via communications interface 1014 may be in the form of signals such as electronic, electromagnetic, optical, or other signals capable of being received by communications interface 1014, via a communications link that carries signals and may be implemented using wire or cable, fiber optics, a phone line, a cellular phone link, a radio frequency link, and/or other communications channels. With such a communications interface 1014, it is contemplated that the one or more processors 1002 might receive information from a network or might output information to the network in the course of performing the above-described method steps. Furthermore, method embodiments may execute solely upon the processors or may execute over a network such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer readable code include machine code, such as produced by a compiler, and files containing higher level code that are executed by a computer using an interpreter. Computer readable media may also be computer code transmitted by a computer data signal to a processor.

In some embodiments, the computer readable media may comprise computer readable code for providing a modification step for less than 0.5 seconds (step 112), computer readable code for providing a first transition from the modification gas to the bombardment gas in less than 0.5 seconds (step 114), computer readable code for providing a removal step for less than 0.5 seconds (step 116), and computer readable code for providing a second transition from the bombardment gas to the modification gas in less than 0.5 seconds (step 118).

In other embodiments, instead of forming the plasma in the reactor where the substrate is located, for the modification step, the plasma may be formed remotely. Radical neutrals may be provided by the remote plasma source. In some embodiments, charged ions are prevented from entering the reactor during the modification step.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. A method for etching features in a carbon containing etch layer, the method comprising a plurality of cycles, wherein each cycle, comprises:
exposing the carbon containing etch layer to oxygen radicals, wherein the oxygen radicals modify part of the carbon containing etch layer; and
exposing the carbon containing etch layer to bombardment ions with an energy of greater than 100 eV for less than 0.5 s for each cycle, wherein the bombardment ions remove the modified part of the carbon containing etch layer to form etched features.

2. The method, as recited in claim 1, wherein the exposing the carbon containing etch layer to the bombardment ions does not cause physical sputtering.

3. The method, as recited in claim 1, wherein the bombardment ions have a flux of greater than 10¹⁷ ions/cm²s.

4. The method, as recited in claim 1, wherein the bombardment ions are ions of one or more of hydrogen (H₂), nitrogen (N₂), helium (He), neon (Ne), argon (Ar), krypton (Kr), and xenon (Xe).

5. The method, as recited in claim 1, wherein the exposing the carbon containing etch layer to bombarding ions exposes the carbon containing etch layer to bombardment ions with an energy in a range of 400 eV to 1500 eV for a period in a range of 0.3 ms to 500 ms for each cycle.

6. The method of claim 1, wherein the oxygen radicals form a self-limiting layer on the etch layer.

7. The method of claim 1, further comprising passivating sidewalls of the etched features.

8. The method, as recited in claim 7, wherein the passivating sidewalls of etched features comprises providing a passivation gas comprising WF₆.

9. The method of claim 8, wherein the providing the passivation gas is at a different time than exposing the carbon containing etch layer to the oxygen radicals and exposing the carbon containing layer to the bombardment ions.

10. The method of claim 8, wherein the providing the passivation gas is simultaneous with at least one of exposing the carbon containing etch layer to the oxygen radicals and exposing the carbon containing layer to the bombardment ions.

11. The method of claim 8, wherein the providing the passivation gas is simultaneous with exposing the carbon containing etch layer to the oxygen radicals.

12. The method, as recited in claim 1, wherein the exposing the carbon containing etch layer to the oxygen radicals, comprises:
providing a modification gas, wherein the modification gas comprises an oxygen containing component; and
transforming the modification gas into a plasma comprising the oxygen radicals.

13. The method, as recited in claim 12, wherein the oxygen containing component comprises at least one of O₂, CO₂, CO, COS, SO₂, and H₂O.

14. The method, as recited in claim 1, further comprising etching at least one layer below the carbon containing etch layer, wherein the carbon containing etch layer is used as a mask.

15. The method of claim 1, further comprising passivating sidewalls of the etched features. by providing a passivation gas comprising at least one of methane (CH₄), fluoromethane (CH₃F), carbon monoxide (CO), carbon dioxide (CO₂), nitrogen (N₂), and boron trichloride (BCl₃).

16. The method of claim 1, further comprising passivating sidewalls of the etched features. by providing a passivation gas to form a passivation layer wherein the passivation layer is at least one of carbon based, silicon based, boron nitride based, and carbon and nitrogen based.

17. An etching system for etching features in a carbon containing etch layer over a substrate, the etching system, comprising:
a processing chamber;
a substrate support for supporting a substrate in the processing chamber;
an RF power source for providing RF power to etch chamber;
an oxygen radical source adapted to provide oxygen radicals in the processing chamber;
a bombardment gas source adapted to provide bombardment gas in the processing chamber;
a controller controllably connected to the RF power source, the oxygen radical source, and the bombardment gas source for a plurality of cycles, configured to:
a) expose the carbon containing etch layer to oxygen, wherein the oxygen radicals are absorbed into the carbon containing etch layer to form a modified part of the carbon containing etch layer; and
b) expose the carbon containing etch layer to bombardment ions, with an energy of greater than 100 eV for less than 0.5 s for each cycle, wherein the bombardment ions remove the modified part of the carbon containing etch layer.

18. The etching system, as recited in claim 17, wherein the exposing the carbon containing etch layer to bombardment ions provides a bias in a range of 400 eV to 1500 eV for a period in a range of 0.3 ms to 500 ms for each cycle.

19. The etching system, as recited in claim 17, wherein the exposing the carbon containing etch layer to bombardment ions does not cause physical sputtering.

20. The etching system, as recited in claim 17, wherein the bombardment gas source provides at least one of hydrogen (H₂), nitrogen (N₂), helium (He), neon (Ne), argon (Ar), krypton (Kr), and xenon (Xe).
